(19) United States
(12) Patent Application Publication
(10) Pub. No.: US 2026/0324074 A1
(43) Pub. Date: Oct. 15, 2026

(54) Array Substrate and Manufacturing Method Therefor

(71) Applicants: Chongqing BOE Optoelectronics Technology Co., Ltd., Chongqing (CN); BOE Technology Group Co., Ltd., Beijing (CN); Beijing BOE Technology Development Co., Ltd., Beijing (CN)

(72) Inventors: Zhiyong NING, Beijing (CN); Chengjun QI, Beijing (CN); Wei SHEN, Beijing (CN); Xu WU, Beijing (CN); Zhonghao HUANG, Beijing (CN); Rui WANG, Beijing (CN); Chunlei WANG, Beijing (CN); Hui GUO, Beijing (CN); Jing CAO, Beijing (CN)

(21) Appl. No.: 18/880,574

(22) PCT Filed: Dec. 27, 2023
(86) PCT No.: PCT/CN2023/142311

§ 371 Date: Jan. 2, 2025

(51) Int. Cl. H10D 86/40; H10D 86/01; H10D 86/60

(52) U.S. Cl. CPC H10D 86/441; H10D 86/0231; H10D 86/60

(57) ABSTRACT

Please replace the abstract with the following amended abstract.

An array substrate and a manufacturing method for the array substrate. The array substrate includes a base substrate (30), a first conductive layer, a second insulation layer, a first insulation layer, and a third conductive layer. The first conductive layer comprises a first conductive part (41) and the third conductive layer comprises a third conductive part (43). The first insulation layer comprises a first through hole (D1), the second insulation layer comprises a second through hole (D2), an orthographic projection of the first through hole (D1) on the base substrate (30) at least partially overlaps with an orthographic projection of the second through hole (D2) on the base substrate (30), and the first through hole (D1) is in communication with the second through hole (D2). A portion of the first conductive part (41) is located in the second through hole (D2).

### CROSS-REFERENCE TO RELATED APPLICATION

The present application is a U.S. National Phase Entry of International Application No. PCT/CN2023/142311 having an international filing date of Dec. 27, 2023, contents of which are incorporated into the present application by reference.

### TECHNICAL FIELD

The present disclosure relates to, but is not limited to, the field of display technologies, and particularly relates to an array substrate and a manufacturing method for the array substrate.

### BACKGROUND

Liquid crystal display (LCD) is a common display type at present. An LCD display uses two pieces of polarized material, and a liquid crystal solution (liquid crystal) is between the two pieces of polarized material. When a voltage is applied to the two pieces of polarized material, the liquid crystal will deflect. By controlling the applied voltage, a degree of liquid crystal deflection may be adjusted. At present, a liquid crystal display (LCD) device is developing towards the goal of light, thin, short and small.

### SUMMARY

The following is a summary of subject matters described herein in detail. This summary is not intended to limit the protection scope of claims.

Embodiments of the present disclosure provide an array substrate and a manufacturing method for the array substrate.

In one aspect, an embodiment of the present disclosure provides an array substrate. The array substrate includes a base substrate, a first conductive layer located on a side of the base substrate, a second insulation layer located on a side of the first conductive layer away from the base substrate, a first insulation layer located on a side of the second insulation layer away from the base substrate, and a third conductive layer located on a side of the first insulation layer away from the base substrate.

The first conductive layer includes a first conductive part and the third conductive layer includes a third conductive part. The first insulation layer includes a first through hole, the second insulation layer includes a second through hole, an orthographic projection of the first through hole on the base substrate at least partially overlaps with an orthographic projection of the second through hole on the base substrate, and the first through hole is in communication with the second through hole.

A portion of the first conductive part is located in the second through hole, a portion of the third conductive part is located in the first through hole and the second through hole, and the first conductive part and the third conductive part are in contact in the second through hole.

In a plane perpendicular to the base substrate, a difference between included angles formed between hole walls of the first through hole and the second through hole and a horizontal plane parallel to the base substrate respectively is Δθ, and 0°≤|Δθ|≤10°.

In an exemplary embodiment, the first through hole includes a first side wall; in the plane perpendicular to the base substrate, there is a gap between the third conductive part and the first side wall, and the gap is greater than 0 nanometer and less than or equal to 50 nanometers.

In an exemplary embodiment, the second through hole includes a second side wall; in the plane perpendicular to the base substrate, there is a gap between the third conductive part and the second side wall, and the gap is greater than 0 nanometer and less than or equal to 50 nanometers.

In an exemplary embodiment, the first through hole includes a first side wall and the second through hole includes a second side wall. In the plane perpendicular to the base substrate, there is a first slope angle between the first side wall and the horizontal plane parallel to the base substrate, there is a second slope angle between the second side wall and the horizontal plane parallel to the base substrate, and both the first slope angle and the second slope angle are greater than or equal to 40 degrees and less than or equal to 50 degrees.

In an exemplary embodiment, the first through hole includes a first side wall, at least a portion of the first side wall protrudes toward a center of the first through hole to form a bulging structure, and a size range of the bulging structure in a radial direction of the first through hole is greater than 0 nanometer and less than or equal to 50 nanometers.

In an exemplary embodiment, the first through hole includes a first side wall and the third conductive part is in full contact with the first side wall.

In an exemplary embodiment, at least a portion of the first side wall is an oblique plane.

In an exemplary embodiment, the first through hole includes a first side wall and the second through hole includes a second side wall. In the plane perpendicular to the base substrate, there is a gap between the third conductive part and the first side wall, the gap is greater than 0 nanometer and less than or equal to 50 nanometers, and the third conductive part is in contact with at least a portion of the second side wall.

In an exemplary embodiment, in the plane perpendicular to the base substrate, there is a gap between the third conductive part and the second side wall, and the gap is greater than 0 nanometer and less than or equal to 50 nanometers.

In an exemplary embodiment, the array substrate includes a display area and a non-display area located on at least one side of the display area. The first through hole and the second through hole are both located in the non-display area.

In an exemplary embodiment, a material of the first insulation layer includes a silicon oxide and a material of the second insulation layer includes a silicon nitride

In an exemplary embodiment, the first through hole includes a first side wall and a material of at least a portion of the first side wall includes a carbon compound.

In another aspect, an embodiment of the present disclosure further provides a manufacturing method for an array substrate, including:
forming a first conductive layer on a side of a base substrate, the first conductive layer including at least one first conductive part;
forming a second insulation thin film on a side of the first conductive layer away from the base substrate;
forming a first insulation thin film on a side of the second insulation thin film away from the base substrate, and patterning the first insulation thin film and the second insulation thin film by a patterning process to form a first insulation layer and a second insulation layer, respectively, the first insulation layer including a first through hole, the second insulation layer including a second through hole, an orthographic projection of the first through hole on the base substrate at least partially overlapping with an orthographic projection of the second through hole on the base substrate, and the first through hole being in communication with the second through hole; and
forming a third conductive layer on a side of the first insulation layer away from the base substrate, the third conductive layer including at least one third conductive part.

A portion of the first conductive part is located in the second through hole, a portion of the third conductive part is located in the first through hole and the second through hole, and the first conductive part and the third conductive part are in contact in the second through hole. In the plane perpendicular to the base substrate, a difference between included angles formed between hole walls of the first through hole and the second through hole and a horizontal plane parallel to the base substrate respectively is Δθ, and 0°<|Δθ|≤10°.

In an exemplary embodiment, patterning the first insulation thin film and the second insulation thin film by a patterning process to form the first insulation layer and the second insulation layer, respectively, includes: forming a photoresist layer on a side of the first insulation thin film away from the base substrate; and exposing the photoresist layer using a mask to form a pattern of photoresist. The pattern of photoresist includes a cover region and a hollow region, the cover region includes a third top wall and a third bottom wall that are provided opposite to each other, and a third side wall connecting the third top wall and the third bottom wall, and the third top wall is further away from the base substrate than the third bottom wall. There is a slope angle between the third side wall and the third bottom wall, and a range of the slope angle is greater than or equal to 80 degrees and less than or equal to 90 degrees.

In an exemplary embodiment, patterning the first insulation thin film and the second insulation thin film by a patterning process to form the first insulation layer and the second insulation layer, respectively, includes: performing a two-step etching process on the first insulation thin film and the second insulation thin film to manufacture the first through hole and the second through hole.

In an exemplary embodiment, the two-step etching process includes a first-step etching and a second-step etching, oxygen in an etching gas used in the first-step etching has a first content ratio, oxygen in an etching gas used in the second-step etching has a second content ratio, and the first content ratio is different from the second content ratio.

In an exemplary embodiment, the second content ratio is greater than the first content ratio.

In an exemplary embodiment, the first content ratio ranges from 20% to 30% and the second content ratio ranges from 30% to 40%.

In an exemplary embodiment, a supply rate of oxygen in the first-step etching ranges from 250 milliliters per minute to 350 milliliters per minute and a supply rate of oxygen in the second-step etching ranges from 450 milliliters per minute to 550 milliliters per minute.

In an exemplary embodiment, patterning the first insulation thin film and the second insulation thin film by a patterning process to form the first insulation layer and the second insulation layer, respectively, further includes: baking the base substrate on which the first insulation layer and the second insulation layer are formed. A temperature range of the baking is from 128 degrees Celsius to 132 degrees Celsius and a time range of the baking is from 105 seconds to 110 seconds.

Other aspects of the present disclosure may be comprehended after the drawings and the detailed description are read and understood.

### BRIEF DESCRIPTION OF DRAWINGS

Accompanying drawings are intended to provide further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of one or more components in the drawings do not reflect actual scales, and are only intended to schematically describe contents of the present disclosure.

FIG. 1 is a schematic front view of an array substrate according to an embodiment of the present disclosure.

FIG. 2 is a schematic partial top view of an array substrate according to an embodiment of the present disclosure.

FIG. 2A is a schematic partial sectional view of an array substrate according to an embodiment of the present disclosure.

FIG. 3 is a schematic partial sectional view of an array substrate according to another embodiment of the present disclosure.

FIG. 4 is a schematic partial sectional view of a conductive structure according to an embodiment of the present disclosure.

FIG. 5 is a first schematic partial sectional view of a conductive structure according to another embodiment of the present disclosure.

FIG. 6 is a second schematic partial sectional view of a conductive structure according to another embodiment of the present disclosure.

FIG. 7 is a third schematic partial sectional view of a conductive structure according to another embodiment of the present disclosure.

FIG. 8 is a fourth schematic partial sectional view of a conductive structure according to another embodiment of the present disclosure.

FIG. 9 is a fifth schematic partial sectional view of a conductive structure according to another embodiment of the present disclosure.

FIG. 10 is a first schematic partial sectional view of a conductive structure according to yet another embodiment of the present disclosure.

FIG. 11 is a second schematic partial sectional view of a conductive structure according to yet another embodiment of the present disclosure.

FIG. 12 is a third schematic partial sectional view of a conductive structure according to yet another embodiment of the present disclosure.

FIG. 13 is a schematic partial sectional view of a conductive structure according to still another embodiment of the present disclosure.

FIGS. 14A to 14J are schematic diagrams of a manufacturing process of an array substrate according to an embodiment of the present disclosure.

### REFERENCE SIGNS

10—pixel electrode, 11—buffer layer, 12—gate insulation layer, 12-1—second insulation thin film, 12-2—initial pattern of the gate insulation layer, 13—first passivation layer, 13-1—third insulation thin film, 13-2—initial pattern of the first passivation layer, 14—planarization layer, 14-1—fourth insulation thin film, 15—second passivation layer, 16—active layer, 16-1—first region, 16-2—second region, 16-3—channel region, 17—gate electrode, 18—common electrode, 20—transistor, 30—base substrate, 40—conductive structure, 41—first conductive part, 42—second conductive part, 43—third conductive part, 50—protrusion structure;
60—photoresist layer, 70—ultraviolet light, 80—pattern of photoresist, 80-1—cover region, 80-2—hollow region, 80-3—third top wall, 80-4—third bottom wall, 80-5—third side wall;
D11—first top wall, D12—first bottom wall, D13—first side wall, D13-1—first portion, D13-2—second portion, D13-3—bevel region, D13-4—curved region, D21—second top wall, D22—second bottom wall, D23—second side wall.

### DETAILED DESCRIPTION

The embodiments of the present disclosure will be described below with reference to the drawings in detail. Implementations may be implemented in multiple different forms. Those of ordinary skills in the art may easily understand such a fact that implementations and contents may be transformed into one or more forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals such as “first”, “second” and “third” in the present disclosure are set to avoid confusion between constituent elements, but not intended for restriction in quantity. In the present disclosure, “a plurality of/multiple” means two or more than two.

In the present disclosure, for convenience, wordings indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the drawings, they are employed for ease of description the specification and simplification of the description only, but do not indicate or imply that the referred device or element must have a particular orientation, or is constructed and operated in a particular orientation, and therefore cannot be construed as limitations on the present disclosure. The positional relationships between the constituent elements are changed as appropriate based on directions according to which the constituent elements are described. Therefore, appropriate replacements based on situations are allowed, and the positional relationships are not limited to the expressions in the specification.

In the present disclosure, the terms “mounting”, “coupling” and “connection” should be understood in a broad sense, unless otherwise explicitly specified and defined. For example, it may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand meanings of the aforementioned terms in the present disclosure according to situations.

In the present disclosure, “electric connection” includes a case where constituent elements are connected through an element with a certain electrical action. An “element with a certain electrical action” is not particularly limited as long as electrical signals may be transmitted between the connected constituent elements. Examples of the “element with a certain electrical action” not only include electrodes and wirings, but also include switching elements such as transistors, resistors, inductors, capacitors, other elements with one or more functions, or the like.

In the present disclosure, a transistor refers to an element including at least three terminals, i.e., a gate electrode, a drain electrode, and a source electrode. The transistor has a channel region between the drain electrode (drain electrode terminal, drain region, or drain) and the source electrode (source electrode terminal, source region, or source), and a current may flow through the drain electrode, the channel region and the source electrode. In the present disclosure, the channel region refers to a region through which a current mainly flows.

In the present disclosure, a first pole may be a drain electrode and a second pole may be a source electrode, or a first pole may be a source electrode and a second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the present disclosure, “film” and “layer” are interchangeable. For example, a “conductive layer” may be replaced with a “conductive film” sometimes. Similarly, an “insulation film” may be replaced with an “insulation layer” sometimes.

In the present disclosure, “about” or “approximately” means that a boundary is defined not so strictly and numerical values within process and measurement error ranges are allowed.

Triangle, rectangle, trapezoid, pentagon, or hexagon and the like in the present disclosure are not strictly defined, and they may be approximate triangle, rectangle, trapezoid, pentagon, or hexagon and the like There may be some small deformations caused by tolerance, and there may be chamfer, arc edge, deformation, and the like.

An embodiment of the present disclosure provides an array substrate. The array substrate includes a base substrate, a first conductive layer located on a side of the base substrate, a second insulation layer located on a side of the first conductive layer away from the base substrate, a first insulation layer located on a side of the second insulation layer away from the base substrate, and a third conductive layer located on a side of the first insulation layer away from the base substrate.

The first conductive layer includes a first conductive part and the third conductive layer includes a third conductive part. The first insulation layer includes a first through hole, the second insulation layer includes a second through hole, an orthographic projection of the first through hole on the base substrate at least partially overlaps with an orthographic projection of the second through hole on the base substrate, and the first through hole is in communication with the second through hole.

A portion of the first conductive part is located in the second through hole, a portion of the third conductive part is located in the first through hole and the second through hole, and the first conductive part and the third conductive part are in contact in the second through hole.

In a plane perpendicular to the base substrate, a difference between included angles formed between hole walls of the first through hole and the second through hole and a horizontal plane parallel to the base substrate respectively is Δθ, and 0°≤|Δθ|≤10°.

In an embodiment of the present disclosure, by defining the difference between the included angles formed between the hole walls of the first through hole and the second through hole and the horizontal plane parallel to the base substrate respectively, it is possible to avoid a large step difference in contact portions between the third conductive part and the hole walls of the first through hole and the second through hole, and it is possible to avoid problems such as poor bonding of the third conductive part in the first through hole and the second through hole, and it is possible to improve the signal transmission capability of the third conductive part.

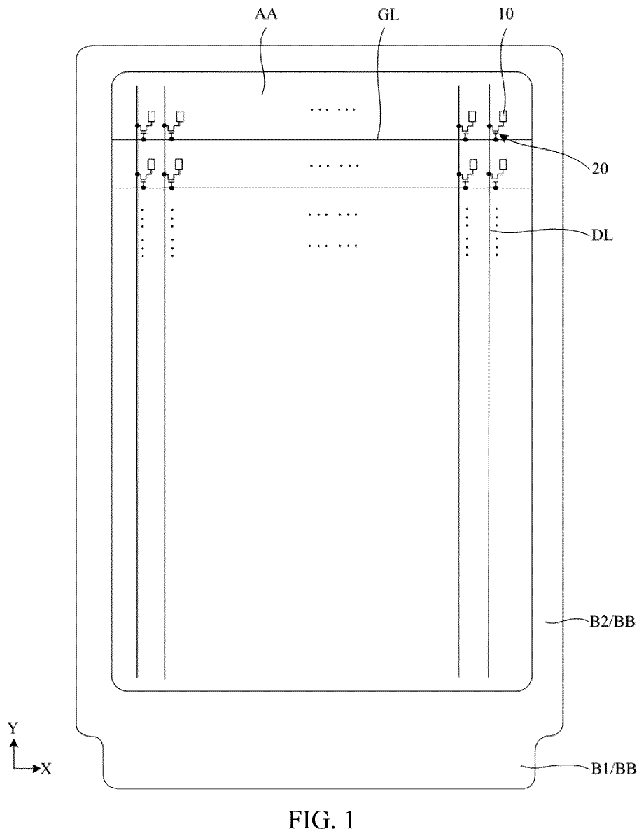

FIG. 1 is a schematic front view of an array substrate according to an embodiment of the present disclosure. As shown in FIG. 1, the array substrate may include a display area AA and a bezel area BB located on at least a side of the display area AA. The bezel area BB may include a first bezel area B1 located on a side of the display area AA and a second bezel area B2 located on remaining sides of the display area AA. For example, the first bezel area B1 may include a lower bezel of the array substrate, and the second bezel area B2 may include an upper bezel, a left bezel, and a right bezel of the array substrate. In an embodiment of the present disclosure, the bezel area may also be referred to as a non-display area.

In an exemplary embodiment, as shown in FIG. 1, the display area AA may include multiple data lines DL and multiple gate lines GL provided on the base substrate. The multiple gate lines GL may extend in a first direction X, and are sequentially arranged along a second direction Y different from the first direction X. The multiple data lines DL may extend in the second direction Y, and are sequentially arranged along the first direction X. The first direction X may intersect with the second direction Y. For example, the first direction X may be perpendicular to the second direction Y. The multiple data lines DL and the multiple gate lines GL may be located in different film layers. For example, the multiple data lines DL may be located on a side of the multiple gate lines GL close to the base substrate.

In an exemplary embodiment, as shown in FIG. 1, the multiple data lines DL and the multiple gate lines GL may intersect to form multiple sub-pixel regions. A region defined by adjacent data lines DL intersecting with adjacent gate lines GL may be a sub-pixel region. One sub-pixel may be correspondingly provided in a sub-pixel region. The sub-pixel region may include an opening region and a non-opening region surrounding the opening region. The non-opening region may be a region that is shielded by a black matrix of an opposed substrate of the array substrate and the opening region may be a region that is not shielded by the black matrix of the opposed substrate. The gate lines GL and the data lines DL that are adjacent may be all located in the non-opening region. The array substrate of an embodiment of the present disclosure may be configured to implement a display function, and the opening region of each sub-pixel region may be configured for display. The non-opening region may surround the opening region and not be configured for display. However, an embodiment of the present disclosure is not limited to this. In some examples, the array substrate may be used for implementing other functions.

In an exemplary embodiment, the display area AA may include multiple pixel units provided on the base substrate. At least one of the pixel units may include three sub-pixels (e.g. a first sub-pixel, a second sub-pixel, and a third sub-pixel arranged sequentially in the first direction X). The three sub-pixels of the pixel unit may be, for example, a blue sub-pixel, a red sub-pixel, and a green sub-pixel, and the three sub-pixels may be arranged sequentially in an order of the blue sub-pixel, the red sub-pixel, and the green sub-pixel. As shown in FIG. 1, at least one sub-pixel may include a pixel electrode 10 and a common electrode (not shown in FIG. 1), and an orthographic projection of the pixel electrode 10 of the sub-pixel on the base substrate may partially overlap with an orthographic projection of the common electrode of the sub-pixel on the base substrate. Common electrodes of multiple sub-pixels in the display area AA may be of an integral structure. For example, the common electrode may be located on a side of the pixel electrode 10 close to the base substrate. The sub-pixel may further include a transistor 20. The transistor 20 may be close to a position where the data line DL and the gate line GL intersect. The transistor 20 may include a gate electrode, a first pole, and a second pole. The gate electrode may be electrically connected with the gate line GL, the first pole of the transistor 20 may be electrically connected with the data line DL, and the second pole may be electrically connected with the pixel electrode 10 of a sub-pixel. The transistor 20 may be configured to supply a data signal transmitted by the data line DL to the pixel electrode 10 of the sub-pixel under control of the gate line GL.

In an exemplary embodiment, the second bezel area B2 may include at least a gate drive circuit (e.g., including multiple cascaded shift registers), and the multiple shift registers may be electrically connected with multiple gate lines GL in the display area AA. The gate drive circuit may also include transistors. A structure of the transistor located in the second bezel area B2 may be the same or different from a structure of the transistor located in the display area AA.

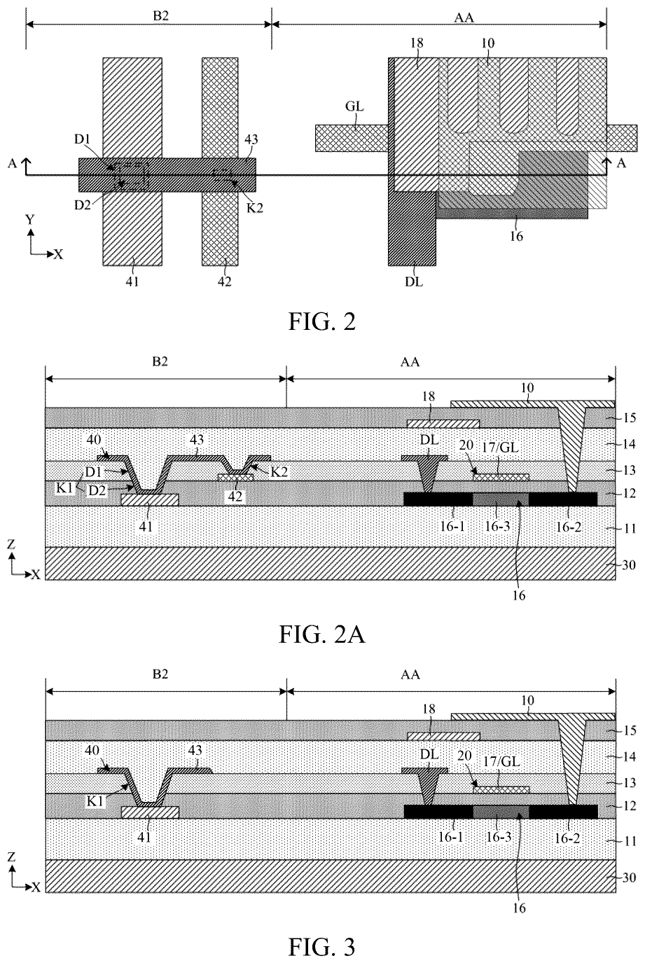

FIG. 2 is a schematic partial top view of an array substrate according to an embodiment of the present disclosure, FIG. 2A is a schematic partial sectional view of an array substrate according to an embodiment of the present disclosure, and FIG. 2A is a schematic sectional view at a line marked A-A in FIG. 2. As shown in FIG. 2A, in an embodiment of the present disclosure, a direction perpendicular to a plane where the array substrate is located is defined as a third direction Z, and the third direction Z may also be referred to as a thickness direction of the array substrate. As shown in FIGS. 2 and 2A, the array substrate may include a base substrate 30, and a first conductive layer, a second conductive layer, a third conductive layer, a fourth conductive layer, and a fifth conductive layer sequentially provided on a side of the base substrate 30. The array substrate may also include a buffer layer 11 located between the base substrate 30 and the first conductive layer, a gate insulation layer 12 located between the first conductive layer and the second conductive layer, a first passivation layer 13 located between the second conductive layer and the third conductive layer, a planarization layer 14 located between the third conductive layer and the fourth conductive layer, and a second passivation layer 15 located between the fourth conductive layer and the fifth conductive layer. In an embodiment of the present disclosure, the first passivation layer may also be referred to as a first insulation layer, and the gate insulation layer may also be referred to as a second insulation layer.

As shown in FIG. 2A, the second bezel area B2 may include multiple conductive structures 40, by way of example, a conductive structure 40 may be configured to connect a gate line with a gate driver. The conductive structure 40 may include a first conductive part 41, a second conductive part 42, and a third conductive part 43. The first conductive part 41 may be located in the first conductive layer, the second conductive part 42 may be located in the second conductive layer, and the third conductive part 43 may be located in the third conductive layer. The conductive structure 40 adopts a multi-layer wiring mode, which may reduce the resistance and improve the signal transmission ability.

As shown in FIG. 2A, the first passivation layer 13 may have multiple vias, and the multiple vias may at least include one first via K1 and one second via K2. The first via K1 exposes at least a portion of a surface of the first conductive part 41 away from the base substrate 30 and the second via K2 exposes at least a portion of a surface of the second conductive part 42 away from the base substrate 30. A portion of the third conductive part 43 may be located in the first via K1 and in contact with at least a portion of a surface of the first conductive part 41 away from the base substrate 30. A portion of the third conductive part 43 may be located in the second via K2 and in contact with at least a portion of a surface of the second conductive part 42 away from the base substrate 30. By way of example, the first conductive part 41 may be configured to be connected with a gate driver, and the gate driver may provide scan signals to sub-pixels in the display area. The second conductive part 42 may be configured to be connected with the gate line.

In an exemplary embodiment, the first via K1 and the second via K2 may be manufactured by a same patterning process, which may simplify the manufacturing process of the array substrate, shorten the manufacturing period of the array substrate, and reduce the manufacturing cost of the array substrate.

In an exemplary embodiment, the base substrate 30 may be a transparent base substrate. For example, the base substrate 30 may be a rigid base substrate or a flexible base substrate. For example, a material of the rigid base substrate may include, but is not limited to, one or more of glass and quartz. A material of the flexible base substrate may include, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. However, an embodiment of the present disclosure is not limited to this.

In an exemplary embodiment, the material of the buffer layer 11, the gate insulation layer 12, the first passivation layer 13, and the second passivation layer 15 may be an inorganic material. Inorganic materials are for example one or more of silicon oxide nitride (SiOₓN_{y}) or silicon nitride (SiNₓ) or silicon oxide (SiOₓ) or the like. The buffer layer 11, the gate insulation layer 12, the first passivation layer 13, and the second passivation layer 15 may be a single layer, a multi-layer, or a composite layer structure.

In an exemplary embodiment, the gate insulation layer 12 and the first passivation layer 13 are of different materials. By way of example, the material of the gate insulation layer 12 may include silicon nitride (SiNₓ), and the material of the first passivation layer 13 may include silicon oxide (SiOₓ).

In an exemplary embodiment, the material of the planarization layer 14 may be an organic material. Organic materials are, for example, any one or more of epoxy resins, phenolic resins, urea-formaldehyde resins, melamine-formaldehyde resins, furan resins, silicone resins, polyester resins, polyamide resins, acrylic resins, polyurethane, vinyl resins, hydrocarbon resins, polyether resins, and the like. The planarization layer 14 may be a single layer or a multi-layer or a composite layer structure. In an embodiment of the present disclosure, a provision of an insulation layer of an organic material may reduce crosstalk of the gate electrode to the common electrode.

In an exemplary embodiment, the first conductive layer, the second conductive layer, and the fourth conductive layer may be made of metallic material(s), for example any one or more of molybdenum (Mo), aluminum (Al), copper (Cu) and titanium (Ti). Alternatively, the first conductive layer, the second conductive layer, and the fourth conductive layer may be made of an alloy material of metallic materials such as molybdenum (Mo), aluminum (Al), copper (Cu), and titanium (Ti), such as, an aluminum-neodymium alloy (AlNd) or a molybdenum-niobium alloy (MoNb), a molybdenum-Nickel-Titanium alloy (MoNiTi). The first conductive layer, the second conductive layer, and the fourth conductive layer may be a mono-layer structure or a multi-layer composite structure, such as Ti/Al/Ti or Mo/Nb/Cu or MoNiTi/Cu or MoNb/Cu/MoNiTi or MoNiTi/Cu/MoNiTi or the like.

In an exemplary embodiment, the material of the third conductive layer and the fifth conductive layer may be a transparent conductive oxide material, and the transparent conductive oxide material may include indium tin oxide (ITO) or indium zinc oxide (IZO). For example, the third conductive layer and the fifth conductive layer may be a mono-layer structure, or a multi-layer composite structure, for example ITO/Al/ITO, or the like. Adopting a transparent conductive oxide material as the material of the conductive layer may improve the climbing ability of the conductive layer, so that the third conductive part 43 and the pixel electrode 10 have relatively stable connection reliability.

In an exemplary embodiment, as shown in FIG. 2A, the display area AA may include multiple transistors 20, multiple data lines DL, multiple gate lines GL, multiple common electrodes 18, and multiple pixel electrodes 10. The transistor 20 may include an active layer 16 and a gate electrode 17 which are stacked, the gate electrode 17 may be located in the second conductive layer, and the active layer 16 may be located on a side of the second conductive layer close to the base substrate 30. By way of example, the active layer 16 and the first conductive layer may be located on a same layer of the array substrate, and the active layer 16 and the first conductive layer are made by different patterning processes. Alternatively, the active layer 16 and the first conductive layer may be located on different layers of the array substrate. The active layer 16 may include a channel region 16-3, and a first region 16-1 and a second region 16-2 located on opposite sides of the channel region 16-3. By way of example, in the process of manufacturing the array substrate, a conductorization process may be performed on a part of the active layer 16, so that portions of the active layer form the first region 16-1 and the second region 16-2, respectively. The first region 16-1 of the active layer 16 may be used as a first pole of the transistor, and the second region 16-2 of the active layer 16 may be used as a second pole of the transistor. By performing a conductorization process on a part of the active layer to form the first pole and the second pole of the transistor respectively, an area of the gate electrode of the transistor can be reduced, the influence of the gate electrode on the aperture ratio of the display area may be avoided, and the aperture ratio of the display area may be improved.

In an exemplary embodiment, as shown in FIG. 2A, an orthographic projection of the gate electrode 17 on a plane where the array substrate is located may at least partially overlap with an orthographic projection of the channel region 16-3 on the plane where the array substrate is located. The gate electrode may block the influence of at least some of the light on the channel region, thereby improving the service performance of the transistor.

In an exemplary embodiment, as shown in FIG. 2A, the fourth conductive layer may include multiple common electrodes 18, the fifth conductive layer may include multiple pixel electrodes 10, and an orthographic projection of the common electrode 18 on the plane where the array substrate is located may at least partially overlap with an orthographic projection of the pixel electrode 10 on the plane where the array substrate is located. In an embodiment of the present disclosure, the pixel electrode may also be referred to as a first electrode of a sub-pixel, and the common electrode may also be referred to as a second electrode of a sub-pixel. Alternatively, the pixel electrode may also be referred to as a second electrode of a sub-pixel, and the common electrode may also be referred to as a first electrode of a sub-pixel.

In an exemplary embodiment, a thickness of the first passivation layer 13 may range from 2000 angstroms to 3000 angstroms.

In an exemplary embodiment, a thickness of the third conductive part 43 may range from 400 angstroms to 700 angstroms.

FIG. 3 is a schematic partial sectional view of an array substrate according to another embodiment of the present disclosure. As shown in FIG. 3, the second bezel are B2 may include multiple conductive structures 40, by way of example, a conductive structure 40 may be configured to connect a gate line with a gate driver. The conductive structure 40 may include a first conductive part 41 and a third conductive part 43. The first conductive part 41 may be located in the first conductive layer and the third conductive part 43 may be located in the third conductive layer. By way of example, the first conductive part 41 may be configured to be connected with the gate line, and the third conductive part 43 may be configured to be connected with the gate driver. In an embodiment of the present disclosure, there is no limitation on the actual type of signal line that adopts the conductive structure to achieve electrical connection.

FIG. 4 is a schematic partial sectional view of a conductive structure according to an embodiment of the present disclosure. As shown in FIG. 4, the first passivation layer 13 may have multiple first through holes D1, and the first through holes D1 penetrate the first passivation layer 13 in the third direction Z. As shown in FIG. 4, the gate insulation layer 12 may have multiple second through holes D2, and the second through holes D2 penetrate the gate insulation layer 12 in the third direction Z. A first via K1 may include a first through hole D1 and a second through hole D2 that are communicated with each other.

As shown in FIG. 4, the first through hole D1 may include a first top wall D11 and a first bottom wall D12 that are provided opposite to each other, and a first side wall D13 connecting the first top wall D11 and the first bottom wall D12. The first top wall D11 is further away from the first conductive part 41 than the first bottom wall D12. There is a first slope angle al between the first side wall D13 and the first bottom wall D12 and an angle range of the first slope angle α1 may be greater than or equal to 40 degrees and less than or equal to 50 degrees, by way of example, the first slope angle α1 may be 45 degrees. By way of example, the first bottom wall D12 may be parallel to the plane where the array substrate is located.

The second through hole D2 may include a second top wall D21 and a second bottom wall D22 that are provided opposite to each other, and a second side wall D23 connecting the second top wall D21 and the second bottom wall D22. The first bottom wall D12 and the second top wall D21 may be coplanar, and the second top wall D21 is further away from the first conductive part 41 than the second bottom wall D22. There is a second slope angle α2 between the second side wall D23 and the second bottom wall D22 and an angle range of the second slope angle α2 may be greater than or equal to 40 degrees and less than or equal to 50 degrees, by way of example, the second slope angle α2 may be 45 degrees. By way of example, the second bottom wall D22 may be parallel to the plane where the array substrate is located.

In an exemplary embodiment, the first slope angle al is less than or equal to the second slope angle α2, which facilitates the transmission of signals from the third conductive part 43 to the first conductive part 41, and can improve the signal transmission capability of the conductive structure 40 as a whole. An absolute value of an angle difference between the first slope angle al and the second slope angle α2 may be less than or equal to 10 degrees. In an embodiment of the present disclosure, the angle difference between the first slope angle α1 and the second slope angle α2 may be denoted as 40.

In an exemplary embodiment, a roughness (Ra) of the first side wall D13 may range from 0.1 microns to 0.2 microns.

In an exemplary embodiment, a roughness (Ra) of the second side wall D23 may range from 0.1 microns to 0.2 microns.

In an exemplary embodiment, the first side wall D13 and the second side wall D23 may be coplanar.

In an exemplary embodiment, the first top wall D11 and the first bottom wall D12 may be parallel to each other. The second top wall D21 and the second bottom wall D22 may be parallel to each other.

In an exemplary embodiment, a flatness of the first top wall D11 may be greater than a flatness of the first bottom wall D12, which facilitates an increase in the contact area between the third conductive part 43 and the first passivation layer 13, and can improve the connection strength between the third conductive part 43 and the first passivation layer 13.

In an exemplary embodiment, the first side wall D13 has a first end and a second end that are provided opposite to each other, and the second end of the first side wall D13 is closer to the second side wall D23 than the first end of the first side wall D13. The second side wall D23 has a first end and a second end that are provided opposite to each other, and the first end of the second side wall D23 is closer to the first side wall D13 than the second end of the second side wall D23, and the second end of the first side wall D13 and the first end of the second side wall D23 are smoothly connected, so that a large step difference may be avoided at the connection between the first side wall D13 and the second side wall D23, and problems such as poor bonding of the third conductive part 43 may be avoided at this connection.

In an exemplary embodiment, an aperture of the second through hole may range from 4.0 microns to 5.0 microns. By way of example, the aperture of the second through hole may be 4.5 microns. An aperture depth of the second through hole may be from 0.8 microns to 1.2 microns. By way of example, the aperture depth of the second through hole may be 1.0 microns.

FIG. 5 is a first schematic partial sectional view of a conductive structure according to another embodiment of the present disclosure. As shown in FIG. 5, at least a portion of the first side wall D13 may be a curved surface. As shown in FIG. 5, the third conductive part 43 is in contact with and fits against the first side wall D13. As shown in FIG. 5, the second side wall D23 may be an oblique plane. The first side wall D13 has a first end and a second end that are provided opposite to each other and the second end of the first side wall D13 is closer to the second side wall D23 than the first end of the first side wall D13. The second side wall D23 has a first end and a second end that are provided opposite to each other, and the first end of the second side wall D23 is closer to the first side wall D13 than the second end of the second side wall D23, and the second end of the first side wall D13 and the first end of the second side wall D23 are smoothly connected, so that a large step difference may be avoided at the connection between the first side wall D13 and the second side wall D23, and problems such as poor bonding of the third conductive part 43 may be avoided at this connection.

In an exemplary embodiment, there is a second slope angle α2 between the second side wall D23 and the second bottom wall D22 and an angle range of the second slope angle α2 may be greater than or equal to 40 degrees and less than or equal to 50 degrees, by way of example, the second slope angle α2 may be 45 degrees. By way of example, the second bottom wall D22 may be parallel to the plane where the array substrate is located. In an embodiment of the present disclosure, taking the first side wall as an example, for the case when the slope angle existing between the first side wall and the plane where the array substrate is located is not a single value, all angle values of the slope angle between the first side wall and the plane where the array substrate is located are satisfied to be greater than or equal to 40 degrees and less than or equal to 50 degrees. Taking the first side wall as an example, for the case where there is a curved surface in the first side wall, in a plane perpendicular to the plane where the array substrate is located, a tangent line is drawn through any point on the first side wall, and the slope angle between the tangent line and the plane where the array substrate is located needs to be greater than or equal to 40 degrees and less than or equal to 50 degrees.

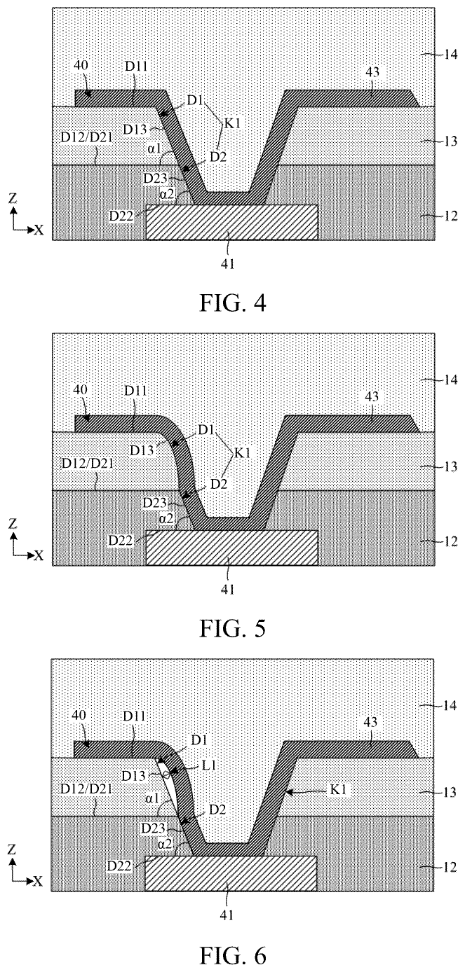

FIG. 6 is a second schematic partial sectional view of a conductive structure according to another embodiment of the present disclosure. As shown in FIG. 6, the first side wall D13 may be an oblique plane, and there is a first slope angle al between the first side wall D13 and the first bottom wall D12. An angle range of the first slope angle α1 may be greater than or equal to 40 degrees and less than or equal to 50 degrees. By way of example, the first slope angle α1 may be 45 degrees. By way of example, the first bottom wall D12 may be parallel to the plane where the array substrate is located.

As shown in FIG. 6, there is a gap L1 between the first side wall D13 and the third conductive part 43, and a range of the gap L1 may be greater than or equal to 0 nanometer and less than or equal to 50 nanometers. In an embodiment of the present disclosure, the gap between the first side wall D13 and the third conductive part 43 is defined as in a plane formed by the first direction X and the third direction Z, a maximum length from any point on an edge of the third conductive part 43 close to the first side wall D13 to a foot of a perpendicular line drawn from that point to an edge of the first side wall D13 close to the third conductive part 43. By limiting the gap L1 to be less than or equal to 50 nanometers, it is possible to ensure that the third conductive part 43 has good bonding strength with the first side wall D13, and it is possible to ensure that the array substrate has high electrical connection reliability. In the process of manufacturing the array substrate, it is necessary to etch the gate insulation layer 12 and the first passivation layer 13 to form the first through hole and the second through hole. After etching, a polymer is usually formed at the hole wall of the first through hole. Before or after forming the third conductive part 43, the polymer may fall off from the hole wall of the first through hole, so that there is a gap between the hole wall of the first through hole and the third conductive part 43. By defining a range of the gap, it is possible to ensure good coverage between the third conductive part 43 and the first side wall, so as to obtain good bonding strength.

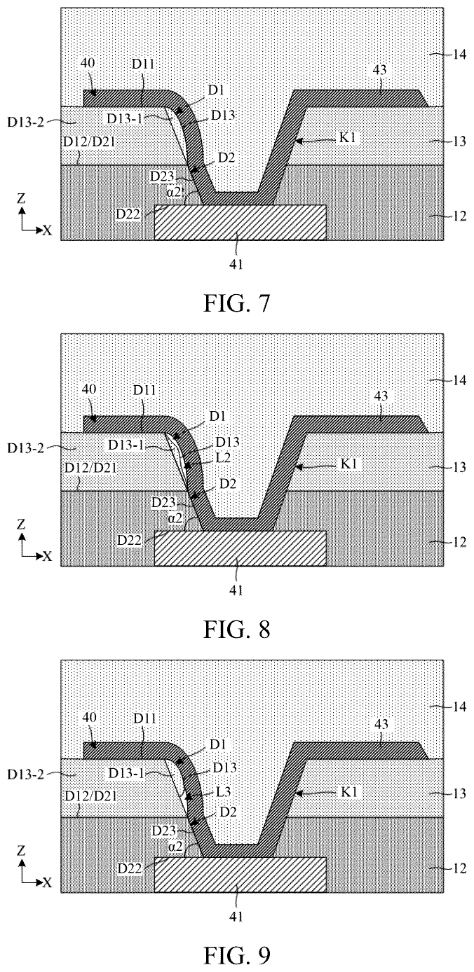

FIG. 7 is a third schematic partial sectional view of a conductive structure according to another embodiment of the present disclosure. As shown in FIG. 7, the first side wall D13 may include a first portion D13-1 and a second portion D13-2, the first portion D13-1 may be located between the second portion D13-2 and the third conductive part 43, and at least a portion of a surface of the first portion D13-1 away from the second portion D13-2 is in contact with the third conductive part 43. By way of example, an entire surface of the first portion D13-1 away from the second portion D13-2 is in contact with the third conductive part 43. The surface where the first portion D13-1 is in contact with and fits against the third conductive part 43 may be a curved surface. In an embodiment of the present disclosure, the first portion may also be referred to as a bulging structure.

In an exemplary embodiment, a material of the first portion D13-1 is different from a material of the second portion D13-2. By way of example, the material of the first portion D13-1 may be a polymer. By way of example, the polymer may at least include a carbon compound. By way of example, the carbon compound may be (CF2) n or the like, n representing a degree of polymerization. A material of the second portion D13-2 may be a silicon oxide (SiOₓ) or the like, by way of example, the silicon oxide may be silicon dioxide.

FIG. 8 is a fourth schematic partial sectional view of a conductive structure according to another embodiment of the present disclosure. As shown in FIG. 8, there is a gap L2 between the first portion D13-1 and the third conductive part 43, and a range of the gap L2 may be greater than or equal to 0 nanometer and less than or equal to 50 nanometers. In an embodiment of the present disclosure, the gap between the first portion D13-1 and the third conductive part 43 is defined as in the plane formed by the first direction X and the third direction Z, a maximum length from any point on an edge of the third conductive part 43 close to the first portion D13-1 to a foot of a perpendicular line drawn from that point to an edge of the first portion D13-1 close to the third conductive part 43. By limiting the gap L2 to be less than or equal to 50 nanometers, it is possible to ensure that the third conductive part 43 has good bonding strength with the first portion D13-1, and it is possible to ensure that the array substrate has high electrical connection reliability.

FIG. 9 is a fifth schematic partial sectional view of a conductive structure according to another embodiment of the present disclosure. As shown in FIG. 9, the first side wall D13 may include a first portion D13-1 and a second portion D13-2. The first portion D13-1 may be located between the second portion D13-2 and the third conductive part 43, and at least a portion of a surface of the first portion D13-1 away from the second portion D13-2 is in contact with and fits against the third conductive part 43. There may be a gap L3 between the second portion D13-2 and the third conductive part 43, and a range of the gap L3 may be greater than or equal to 0 nanometer and less than or equal to 50 nanometers.

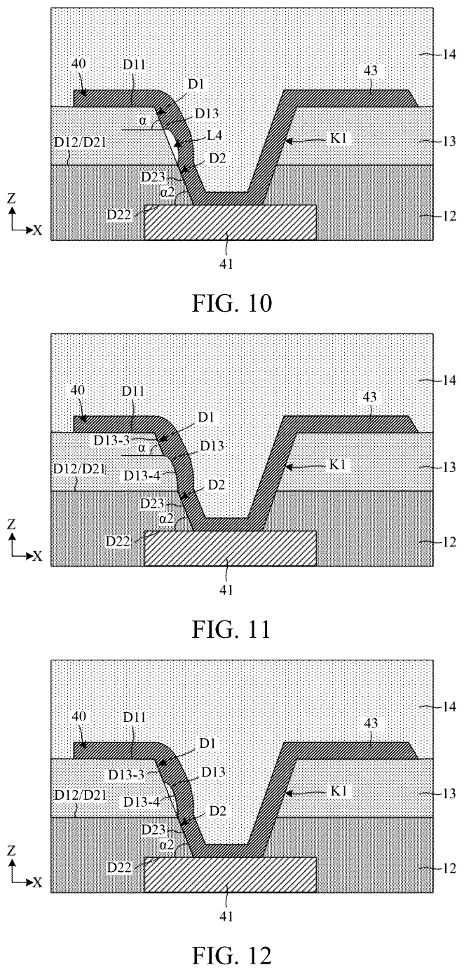

FIG. 10 is a first schematic partial sectional view of a conductive structure according to yet another embodiment of the present disclosure. As shown in FIG. 10, a portion of the first side wall D13 is in contact with and fits against the third conductive part 43, and a portion of the first side wall D13 that is in contact with and fits against the third conductive part 43 may be an oblique plane. There is a gap L4 between the first side wall D13 and the third conductive part 43 and a range of the gap LA may be greater than or equal to 0 nanometer and less than or equal to 50 nanometers.

In an exemplary embodiment, there is a slope angle a between a portion of the first side wall D13 that is in contact with and fits against the third conductive part 43 and a plane where the array substrate is located. An angle range of the slope angle a may be greater than or equal to 40 degrees and less than or equal to 50 degrees. By way of example, the slope angle a may be 45 degrees.

FIG. 11 is a second schematic partial sectional view of a conductive structure according to yet another embodiment of the present disclosure. As shown in FIG. 11, the first side wall D13 may include a bevel region D13-3 and a curved region D13-4 that are connected with each other. The bevel region D13-3 includes a first end and a second end that are provided opposite to each other, the first end of the bevel region D13-3 may be connected with the first top wall D11, and the second end of the bevel region D13-3 may extend towards the first bottom wall D12. The curved region D13-4 includes a first end and a second end that are provided opposite to each other, the first end of the curved region D13-4 may be connected with the second end of the bezel region D13-3, and the second end of the curved region D13-4 may extend towards and be connected with the first bottom wall D12.

In an exemplary embodiment, there may be a slope angle a between the bevel region D13-3 and the plane where the array substrate is located. An angle range of the slope angle a may be greater than or equal to 40 degrees and less than or equal to 50 degrees, by way of example, the slope angle a may be 45 degrees.

FIG. 12 is a third schematic partial sectional view of a conductive structure according to yet another embodiment of the present disclosure. As shown in FIG. 12, the first side wall D13 may include a bevel region D13-3 and a curved region D13-4 that are connected with each other. A material of the bevel region D13-3 may be a silicon oxide (SiOₓ) or the like, by way of example, the silicon oxide may be silicon dioxide. A material of the curved region D13-4 may be a polymer, by way of example, the polymer may at least include a carbon compound.

FIG. 13 is a schematic partial sectional view of a conductive structure according to still another embodiment of the present disclosure. As shown in FIG. 13, the array substrate may further include at least one protrusion structure 50, the at least one protrusion structure 50 may be located at an aperture bottom of the first via K1, and the third conductive part 43 is in contact with and fits against the at least one protrusion structure 50. As shown in FIG. 13, multiple protrusion structures 50 may be arranged at intervals in the first direction X.

In an exemplary embodiment, in the plane formed by the first direction X and the third direction Z, a section of the protrusion structure 50 may be semi-circular, trapezoidal, semi-elliptical, or the like.

In an exemplary embodiment, a height of the protrusion structure 50 (in the third direction Z) may range from 20 nanometers to 30 nanometers.

A structure of an array substrate is described below by an example of a manufacturing process of the array substrate. A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition process may be any one or more of sputtering, evaporation, and chemical vapor deposition, coating process may be any one or more of spray coating, spin coating, and inkjet printing, and etching process may be any one or more of dry etching and wet etching, the present disclosure is not limited thereto. A “thin film” refers to a layer of thin film made of a material on a base substrate by using deposition, coating, or another process. If the “thin film” does not need to be processed through a patterning process in the entire manufacturing process, the “thin film” may also be called a “layer”. If the “thin film” needs to be processed through a patterning process in the entire manufacturing process, the “thin film” is called a “thin film” before the patterning process is performed and is called a “layer” after the patterning process is performed. At least one “pattern” is contained in the “layer” which has been processed through the patterning process. In the present disclosure, “A and B are of a same layer structure” means that A and B are formed through a same one-time patterning process.

A manufacturing process of an array substrate may include the following steps, and only one structure of the array substrate is taken as an example.

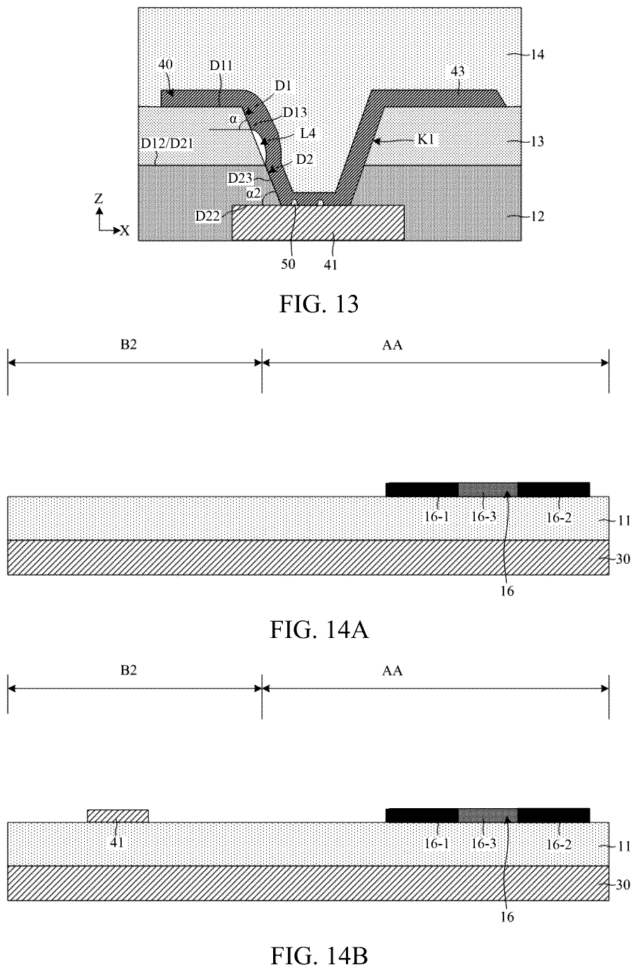

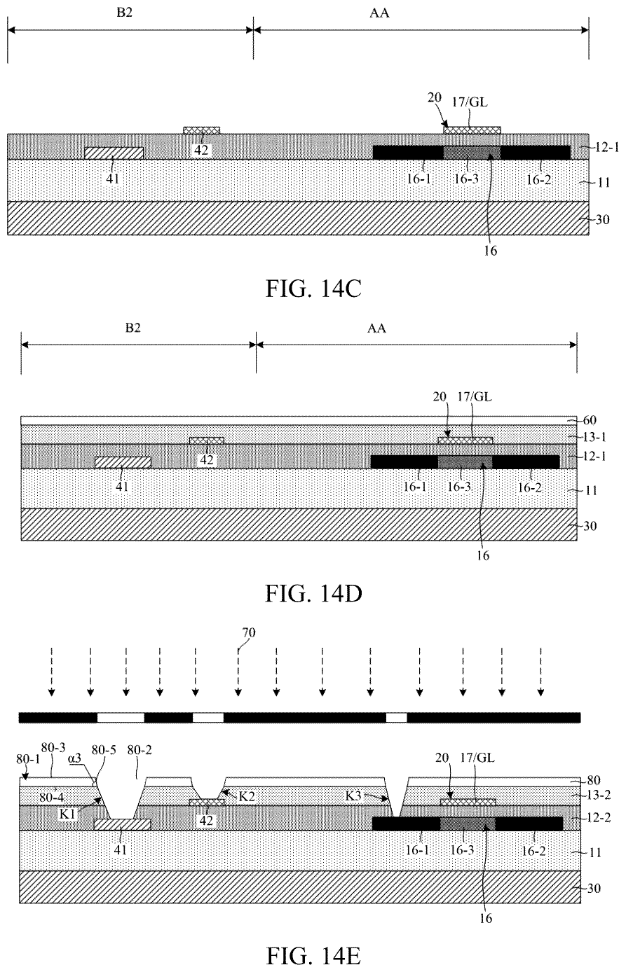

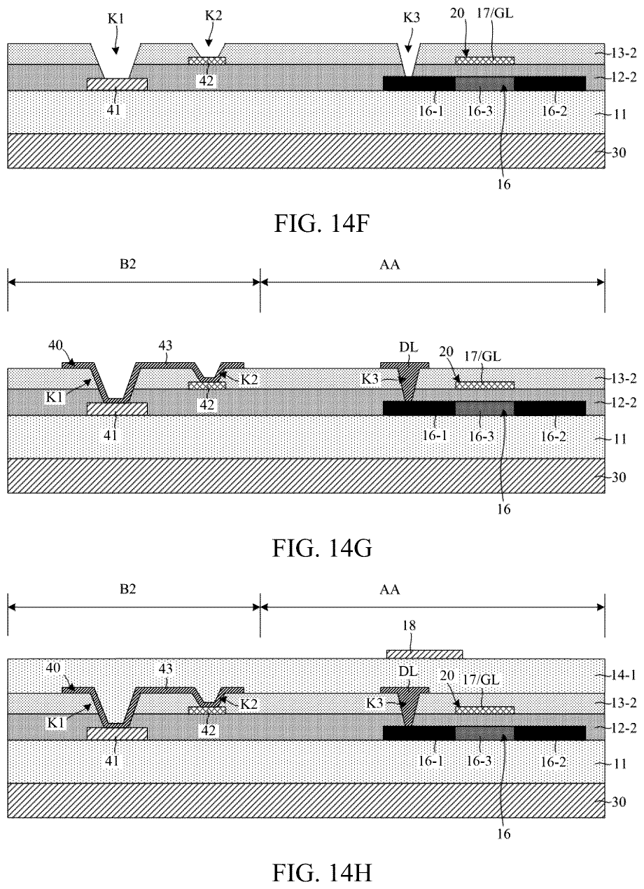

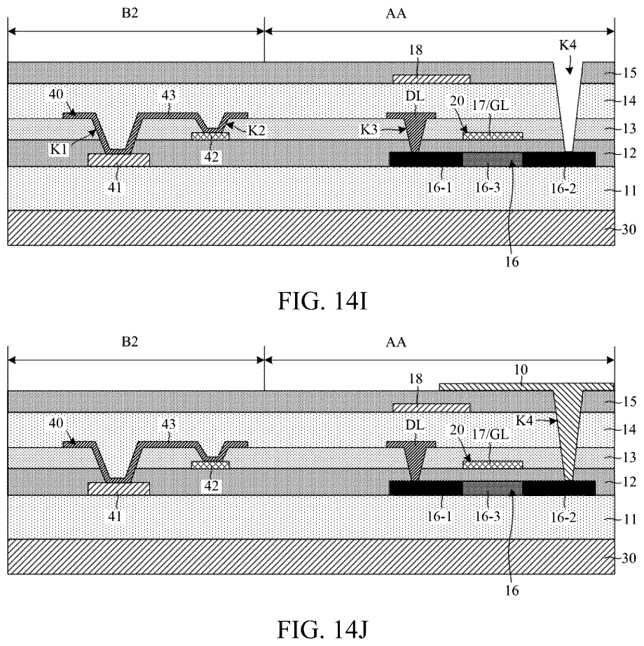

(11) Forming a pattern of a semiconductor layer. Forming the pattern of the semiconductor layer may include depositing a first insulation thin film and a semiconductor thin film on a side of the base substrate 30, and patterning the semiconductor thin film by a patterning process to form the pattern of the semiconductor layer on a side of the buffer layer 11 away from the base substrate 30. The semiconductor layer may include an active layer 16 of a transistor, and the pattern of the semiconductor layer may be located in a display area AA of the array substrate as shown in FIG. 14A.

As shown in FIG. 14A, forming the pattern of the semiconductor layer may also include performing a conductorization processing on a portion of the active layer 16 by using a mask, so that portions of the active layer 16 form a first region 16-1 and a second region 16-2, respectively. The first region 16-1 of the active layer 16 may be used as a first pole of the transistor, and the second region 16-2 of the active layer 16 may be used as a second pole of the transistor.

(12) Forming a pattern of a first conductive layer. Forming the pattern of the first conductive layer may include depositing a first conductive thin film on a side of the base substrate 30 on which the aforementioned patterns are formed, and patterning the first conductive thin film by a patterning process to form the pattern of the first conductive layer on a side of the base substrate 30. The first conductive layer may include multiple first conductive parts 41 and the multiple first conductive parts 41 may be located in the second bezel area B2 of the array substrate as shown in FIG. 14B.

(13) Forming a pattern of a second conductive layer. Forming the pattern of the second conductive layer may include sequentially depositing a second insulation thin film 12-1 and a second conductive thin film on a side of the base substrate 30 on which the aforementioned patterns are formed, and patterning the second conductive thin film by a patterning process to form the pattern of the second conductive layer on a side of the second insulation thin film 12-1 away from the base substrate 30. The second conductive layer may include multiple second conductive parts 42, multiple gate lines GL, and multiple gate electrodes 17, and as shown in FIG. 14C, the multiple gate lines GL and the multiple gate electrodes 17 may be located in the display area AA of the array substrate. The multiple second conductive parts 42 may be located in the second bezel area B2 of the array substrate.

As shown in FIG. 14C, an orthographic projection of the first conductive part 41 on the plane where the array substrate is located does not overlap with an orthographic projection of the second conductive part 42 on the plane where the array substrate is located.

As shown in FIG. 14C, an orthographic projection of the gate electrode 17 on the plane where the array substrate is located may at least partially overlap with an orthographic projection of the channel region 16-3 on the plane where the array substrate is located, and the gate electrode may block the influence of at least some of the light on the channel region, thereby improving the service performance of the transistor.

(14) Forming an initial pattern of a first passivation layer. Forming the initial pattern of the first passivation layer may include sequentially forming a third insulation thin film 13-1 and a photoresist layer 60 on a side of the base substrate 30 on which the aforementioned patterns are formed, as shown in FIG. 14D. By way of example, a thickness of the photoresist layer 60 may range from 2.5 microns to 3.5 microns.

Forming the initial pattern of the first passivation layer may also include exposing the photoresist layer 60 by ultraviolet light 70 using a mask to form a pattern of photoresist 80, then using an etching process to form an initial pattern of the gate insulation layer 12-2 from the second insulation thin film and to form the initial pattern of the first passivation layer 13-2 from the third insulation thin film 13-1, as shown in FIG. 14E, and then peeling off the pattern of photoresist, as shown in FIG. 14F.

As shown in FIG. 14E, the pattern of photoresist 80 may include a cover region 80-1 and a hollow region 80-2, and the cover region 80-1 may be provided around the hollow region 80-2. A shape of an orthographic projection of the hollow region 80-2 on the plane where the array substrate is located may be circular, rectangular, hexagonal, elliptical, or the like.

As shown in FIG. 14E, the cover region 80-1 may include a third top wall 80-3, a third bottom wall 80-4 that are provided opposite to each other, and a third side wall 80-5 connecting the third top wall 80-3 and the third bottom wall 80-4. The third top wall 80-3 is further away from the initial pattern of the first passivation layer 13-2 than the third bottom wall 80-4. There is a third slope angle α3 between the third side wall 80-5 and the third bottom wall 80-4, and an angle range of the third slope angle α3 may be greater than or equal to 80 degrees and less than or equal to 90 degrees, by way of example, the third slope angle α3 may be 85 degrees. In an embodiment of the present disclosure, by defining the angle range of the third slope angle α3, the cover region 80-1 may better shield the hole walls of the first through hole K1, the second through hole K2, and the third through hole K3 to be formed subsequently, the third conductive part and the data line to be formed subsequently may have better connection performance with the vias, and the reliability of the electrical connection of the array substrate may be improved.

As shown in FIG. 14E, the initial pattern of the first passivation layer 13-2 may have multiple vias, and the multiple vias may include a first via K1, a second via K2, and a third via K3. The third insulation thin film and the second insulation thin film in the first via K1 are both etched off, the first via K1 exposes at least a portion of a surface of the first conductive part 41 away from the base substrate 30, and the first via K1 is configured such that the third conductive part to be formed subsequently is connected with the first conductive part 41 via the first via. The third insulation thin film in the second via K2 is etched off, and the second via K2 exposes at least a portion of a surface of the second conductive part 42 away from the base substrate 30, and the second via K2 is configured such that the third conductive part to be formed subsequently is connected with the second conductive part 42 via the second via. The third insulation thin film and the second insulation thin film in the third via K3 are both etched off, and the third via K3 exposes at least a portion of a surface of the first region 16-1 away from the base substrate 30, and the third via K3 is configured such that a data line to be formed subsequently is connected with the first region 16-1 via the third via.

In an exemplary embodiment, the first via K1 may be manufactured by a two-step etching process. The two-step etching process may include a first-step etching and a second-step etching. In the first-step etching, oxygen has a first content ratio. In an embodiment of the present disclosure, a content ratio of oxygen is a percentage of a total amount of oxygen to a total amount of etching gas, and the etching gas includes oxygen. In the second-step etching, the oxygen has a second content ratio, and the second content ratio is greater than the first content ratio. The first content ratio may range from 20% to 30%. By way of example, the first content ratio may be 25%. The second content ratio may range from 30% to 40%, by way of example, the second content ratio may be 35%, or the second content ratio may be 36% or the like. By configuring the first via K1 to be manufactured from a two-step etching process, and limiting an oxygen content ratio in the first-step etching process to be lower than an oxygen content ratio in the second-step etching process, it is possible to ensure that the photoresist in the cover region 80-1 will not be over-oxidized, allowing the cover region 80-1 to better cover the first top wall of the first via. Additionally, a polymer formed in the etching process may be effectively removed, the cover and contact performance between the film layer to be formed subsequently and the via may be ensured, and the connection performance of the array substrate may be improved.

In an exemplary embodiment, in the first-step etching, a supply rate of oxygen may range from 250 milliliters per minute (sccm) to 350 milliliters per minute (sccm). By way of example, the supply rate of oxygen may be 300 milliliters per minute.

In an exemplary embodiment, in the second-step etching, a supply rate of oxygen may range from 450 milliliters per minute (sccm) to 550 milliliters per minute (sccm). By way of example, the supply rate of oxygen may be 500 milliliters per minute.

In an exemplary embodiment, an etching gas may include tetrafluoromethane (CF4) or the like. For example, the tetrafluoromethane supply rate may range from 850 milliliters per minute (sccm) to 950 milliliters per minute (sccm). By way of example, the tetrafluoromethane supply rate may be 900 milliliters per minute.

In an exemplary embodiment, forming the initial pattern of the first passivation layer may further include baking the initial pattern of the first passivation layer. A temperature range of the baking may be from 128 degrees Celsius to 132 degrees Celsius and a time range of the baking may be from 105 seconds to 110 seconds. By way of example, the initial pattern of the first passivation layer may be continuously baked for 108 seconds at 130 degrees Celsius.

In an exemplary embodiment, an adhesive material of the photoresist layer 60 may include a photosensitive resin, an additive, a solvent, and the like.

(15) Forming a pattern of a third conductive layer. Forming the pattern of the third conductive layer may include depositing a third conductive thin film on a side of the base substrate 30 on which the aforementioned patterns are formed, and patterning the third conductive thin film by a patterning process to form the pattern of the third conductive layer on a side of the initial pattern of the first passivation layer 13-2 away from the base substrate 30. The third conductive layer may include multiple third conductive parts 43 and multiple data lines DL, as shown in FIG. 14G.

As shown in FIG. 14G, the third conductive part 43 may be connected with the first conductive part 41 via the first via K1, and may be connected with the second conductive part 42 via the second via K2. The data line DL may be connected with the first region 16-1 via the third via K3.

(16) Forming a pattern of a fourth conductive layer. Forming the pattern of the fourth conductive layer may include sequentially depositing a fourth insulation thin film 14-1 and a fourth conductive thin film on a side of the base substrate 30 on which the aforementioned patterns are formed, and patterning the fourth conductive thin film by a patterning process to form the pattern of the fourth conductive layer on a side of the fourth insulation thin film 14-1 away from the base substrate 30. The fourth conductive layer may include a common electrode 18, as shown in FIG. 14H.

(17) Forming a pattern of a second passivation layer. Forming the pattern of the second passivation layer may include depositing a fifth insulation thin film on a side of the base substrate 30 on which the aforementioned patterns are formed, and patterning the fifth insulation thin film by a patterning process to form the pattern of the second passivation layer on a side of the fourth conductive layer away from the base substrate 30. The second passivation layer 15 may include multiple communication holes K4, as shown in FIG. 14I.

As shown in FIG. 14I, the fifth insulation thin film, the fourth insulation thin film, the third insulation thin film, and the second insulation thin film located in the communication hole K4 are all etched off, and at least a portion of a surface of the second region 16-2 away from the base substrate 30 is exposed. The communication hole K4 is configured such that a pixel electrode to be formed subsequently is connected with the second region 16-2 via the communication hole.

(18) Forming a pattern of a fifth conductive layer. Forming the pattern of the fifth conductive layer may include depositing a fifth conductive thin film on a side of the base substrate 30 on which the aforementioned patterns are formed, and patterning the fifth conductive thin film by a patterning process to form the pattern of the fifth conductive layer on a side of the second passivation layer 15 away from the base substrate 30. The fifth conductive layer may include a pixel electrode 10, as shown in FIG. 14J.

As shown in FIG. 14J, a portion of the pixel electrode 10 may be located in the communication hole K4 and connected with the second region 16-2.

An embodiment of the present disclosure further provides a manufacturing method for an array substrate, including:
forming a first conductive layer on a side of a base substrate, the first conductive layer including at least one first conductive part;
forming a second insulation thin film on a side of the first conductive layer away from the base substrate;
forming a first insulation thin film on a side of the second insulation thin film away from the base substrate, and patterning the first insulation thin film and the second insulation thin film by a patterning process to form a first insulation layer and a second insulation layer, respectively, the first insulation layer including a first through hole, the second insulation layer including a second through hole, an orthographic projection of the first through hole on the base substrate at least partially overlapping with an orthographic projection of the second through hole on the base substrate, and the first through hole being in communication with the second through hole; and
forming a third conductive layer on a side of the first insulation layer away from the base substrate, the third conductive layer including at least one third conductive part.

A portion of the first conductive part is located in the second through hole, a portion of the third conductive part is located in the first through hole and the second through hole, and the first conductive part and the third conductive part are in contact in the second through hole. In a plane perpendicular to the base substrate, a difference between included angles formed between hole walls of the first through hole and the second through hole and a horizontal plane parallel to the base substrate respectively is Δθ, and 0°≤|Δθ|≤10°.

In an exemplary embodiment, patterning the first insulation thin film and the second insulation thin film by a patterning process to form the first insulation layer and the second insulation layer, respectively, includes: forming a photoresist layer on a side of the first insulation thin film away from the base substrate; and exposing the photoresist layer using a mask to form a pattern of photoresist, the pattern of photoresist including a cover region and a hollow region, the cover region including a third top wall and a third bottom wall that are provided opposite to each other, and a third side wall connecting the third top wall and the third bottom wall, the third top wall being further away from the base substrate than the third bottom wall. There is a slope angle between the third side wall and the third bottom wall, and a range of the slope angle may be greater than or equal to 80 degrees and less than or equal to 90 degrees.

In an exemplary embodiment, patterning the first insulation thin film and the second insulation thin film by a patterning process to form the first insulation layer and the second insulation layer, respectively, includes: performing a two-step etching process on the first insulation thin film and the second insulation thin film to manufacture the first through hole and the second through hole.

In an exemplary embodiment, the two-step etching process includes a first-step etching and a second-step etching, oxygen in an etching gas used in the first-step etching has a first content ratio, oxygen in an etching gas used in the second-step etching has a second content ratio, and the first content ratio is different from the second content ratio.

In an exemplary embodiment, the second content ratio is greater than the first content ratio.

In an exemplary embodiment, the first content ratio ranges from 20% to 30% and the second content ratio ranges from 30% to 40%.

In an exemplary embodiment, a supply rate of oxygen in the first-step etching ranges from 250 milliliters per minute to 350 milliliters per minute, and a supply rate of oxygen in the second-step etching ranges from 450 milliliters per minute to 550 milliliters per minute.

In an exemplary embodiment, patterning the first insulation thin film and the second insulation thin film by a patterning process to form the first insulation layer and the second insulation layer, respectively, further includes: baking the base substrate on which the first insulation layer and the second insulation layer are formed. A temperature range of the baking is from 128 degrees Celsius to 132 degrees Celsius and a time range of the baking is from 105 seconds to 110 seconds.

An embodiment of the present disclosure further provides a display device. The display device includes the array substrate described in any one of the foregoing embodiments. The display device may be any product or component with a display function such as liquid crystal panel, electronic paper, a mobile phone, a tablet computer, a television, a display, a notebook computer, a digital photo frame, a navigator. However, this is not limited in the embodiments of the present disclosure.

Although the embodiments disclosed in the present disclosure are described as above, the described contents are only embodiments which are adopted in order to facilitate understanding of the present disclosure, and are not intended to limit the present disclosure. It should be noted that the above examples or embodiments are exemplary only and not restrictive. Therefore, the present disclosure is not limited to what is specifically shown and described herein. Various modifications, substitutions or omissions may be made in forms and details of implementation modes without departing from the scope of the present disclosure.

1. An array substrate, comprising a base substrate, a first conductive layer located on a side of the base substrate, a second insulation layer located on a side of the first conductive layer away from the base substrate, a first insulation layer located on a side of the second insulation layer away from the base substrate, and a third conductive layer located on a side of the first insulation layer away from the base substrate;
wherein the first conductive layer comprises a first conductive part and the third conductive layer comprises a third conductive part; the first insulation layer comprises a first through hole, the second insulation layer comprises a second through hole, an orthographic projection of the first through hole on the base substrate at least partially overlaps with an orthographic projection of the second through hole on the base substrate, and the first through hole is in communication with the second through hole;
wherein a portion of the first conductive part is located in the second through hole, a portion of the third conductive part is located in the first through hole and the second through hole, and the first conductive part and the third conductive part are in contact in the second through hole; and
wherein in a plane perpendicular to the base substrate, a difference between included angles formed between hole walls of the first through hole and the second through hole and a horizontal plane parallel to the base substrate respectively is Δθ, and 0°≤|Δθ|≤10°.

2. The array substrate according to claim 1, wherein the first through hole comprises a first side wall; in the plane perpendicular to the base substrate, there is a gap between the third conductive part and the first side wall, and the gap is greater than 0 nanometer and less than or equal to 50 nanometers.

3. The array substrate according to claim 1, wherein the second through hole comprises a second side wall; in the plane perpendicular to the base substrate, there is a gap between the third conductive part and the second side wall, and the gap is greater than 0 nanometer and less than or equal to 50 nanometers.

4. The array substrate according to claim 1, wherein the first through hole comprises a first side wall and the second through hole comprises a second side wall; in the plane perpendicular to the base substrate, there is a first slope angle between the first side wall and the horizontal plane parallel to the base substrate, there is a second slope angle between the second side wall and the horizontal plane parallel to the base substrate, and both the first slope angle and the second slope angle are greater than or equal to 40 degrees and less than or equal to 50 degrees.

5. The array substrate according to claim 1, wherein the first through hole comprises a first side wall, at least a portion of the first side wall protrudes toward a center of the first through hole to form a bulging structure, and a size range of the bulging structure in a radial direction of the first through hole is greater than 0 nanometer and less than or equal to 50 nanometers.

6. The array substrate according to claim 1, wherein the first through hole comprises a first side wall and the third conductive part is in full contact with the first side wall.

7. The array substrate according to claim 6, wherein at least a portion of the first side wall is an oblique plane.

8. The array substrate according to claim 1, wherein the first through hole comprises a first side wall and the second through hole comprises a second side wall; in the plane perpendicular to the base substrate, there is a gap between the third conductive part and the first side wall, the gap is greater than 0 nanometer and less than or equal to 50 nanometers, and the third conductive part is in contact with at least a portion of the second side wall.

9. The array substrate according to claim 8, wherein in the plane perpendicular to the base substrate, there is a gap between the third conductive part and the second side wall, and the gap is greater than 0 nanometer and less than or equal to 50 nanometers.

10. The array substrate according to claim 1, wherein the array substrate comprises a display area and a non-display area located on at least one side of the display area and the first through hole and the second through hole are both located in the non-display area.

11. The array substrate according to claim 1, wherein a material of the first insulation layer comprises a silicon oxide and a material of the second insulation layer comprises a silicon nitride.

12. The array substrate according to claim 1, wherein the first through hole comprises a first side wall and a material of at least a portion of the first side wall comprises a carbon compound.

13. A manufacturing method for an array substrate, comprising:
forming a first conductive layer on a side of a base substrate, the first conductive layer comprising at least one first conductive part;
forming a second insulation thin film on a side of the first conductive layer away from the base substrate;
forming a first insulation thin film on a side of the second insulation thin film away from the base substrate, and patterning the first insulation thin film and the second insulation thin film by a patterning process to form a first insulation layer and a second insulation layer, respectively, wherein the first insulation layer comprises a first through hole, the second insulation layer comprises a second through hole, an orthographic projection of the first through hole on the base substrate at least partially overlaps with an orthographic projection of the second through hole on the base substrate, and the first through hole is in communication with the second through hole; and
forming a third conductive layer on a side of the first insulation layer away from the base substrate, the third conductive layer comprising at least one third conductive part;
wherein a portion of the first conductive part is located in the second through hole, a portion of the third conductive part is located in the first through hole and the second through hole, and the first conductive part and the third conductive part are in contact in the second through hole; in the plane perpendicular to the base substrate, a difference between included angles formed between hole walls of the first through hole and the second through hole and a horizontal plane parallel to the base substrate respectively is Δθ, and 0°≤|Δθ|≤10°.

14. The manufacturing method for the array substrate according to claim 13, wherein patterning the first insulation thin film and the second insulation thin film by a patterning process to form the first insulation layer and the second insulation layer, respectively, comprises:
forming a photoresist layer on a side of the first insulation thin film away from the base substrate; and
exposing the photoresist layer using a mask to form a pattern of photoresist, wherein the pattern of photoresist comprises a cover region and a hollow region, the cover region comprises a third top wall and a third bottom wall that are provided opposite to each other, and a third side wall connecting the third top wall and the third bottom wall, the third top wall is further away from the base substrate than the third bottom wall, there is a slope angle between the third side wall and the third bottom wall, and a range of the slope angle is greater than or equal to 80 degrees and less than or equal to 90 degrees.

15. The manufacturing method for the array substrate according to claim 13, wherein patterning the first insulation thin film and the second insulation thin film by a patterning process to form the first insulation layer and the second insulation layer, respectively, comprises:
performing a two-step etching process on the first insulation thin film and the second insulation thin film to manufacture the first through hole and the second through hole.

16. The manufacturing method for the array substrate according to claim 15, wherein the two-step etching process comprises a first-step etching and a second-step etching, oxygen in an etching gas used in the first-step etching has a first content ratio, oxygen in an etching gas used in the second-step etching has a second content ratio, and the first content ratio is different from the second content ratio.

17. The manufacturing method for the array substrate according to claim 16, wherein the second content ratio is greater than the first content ratio.

18. The manufacturing method for the array substrate according to claim 16, wherein the first content ratio ranges from 20% to 30% and the second content ratio ranges from 30% to 40%.

19. The manufacturing method for the array substrate according to claim 16, wherein a supply rate of oxygen in the first-step etching ranges from 250 milliliters per minute to 350 milliliters per minute and a supply rate of oxygen in the second-step etching ranges from 450 milliliters per minute to 550 milliliters per minute.

20. The manufacturing method for the array substrate according to claim 13, wherein patterning the first insulation thin film and the second insulation thin film by a patterning process to form the first insulation layer and the second insulation layer, respectively, further comprises:
baking the base substrate on which the first insulation layer and the second insulation layer are formed, a temperature range of the baking being from 128 degrees Celsius to 132 degrees Celsius, and a time range of the baking being from 105 seconds to 110 seconds.
